(19) United States
(12) Patent Application Publication
(10) Pub. No.: US 2019/0194365 A1
(43) Pub. Date: Jun. 27, 2019

(54) COMPOSITION, MODIFICATION METHOD AND SELECTIVE MODIFICATION METHOD OF BASE MATERIAL SURFACE, PATTERN-FORMING METHOD, AND POLYMER

(71) Applicant: JSR CORPORATION, Tokyo (JP)

(72) Inventors: Hiroyuki KOMATSU, Tokyo (JP); Tomohiro ODA, Tokyo (JP); Masafumi HORI, Tokyo (JP); Hitoshi OSAKI, Tokyo (JP); Takehiko NARUOKA, Tokyo (JP)

(73) Assignee: JSR CORPORATION, Tokyo (JP)

(21) Appl. No.: 16/289,938

(22) Filed: Mar. 1, 2019

Related U.S. Application Data
(63) Continuation of application No. PCT/JP2017/031678, filed on Sep. 1, 2017.

(30) Foreign Application Priority Data
Sep. 2, 2016 (JP) 2016-172298

(51) Int. Cl. C08F 12/20; C23C 16/455; C08F 12/08; C08F 20/22; B05D 7/24; B05D 7/14; B05D 3/10; B05D 3/14

(52) U.S. Cl. CPC C08F 12/20; C23C 16/45525; C08F 12/08; C08F 20/22; B05D 3/02; B05D 7/14; B05D 3/107; B05D 3/148; B05D 7/24

(57) ABSTRACT

A composition includes a first polymer and a solvent. The first polymer includes a first structural unit including a fluorine atom, and a group including a first functional group at an end of a main chain or a side chain of the first polymer. The first functional group is capable of forming a bond with a metal or a metalloid. The first structural unit preferably includes a fluorinated hydrocarbon group. The first structural unit is preferably derived from a (meth)acrylic ester containing a fluorine atom, or a styrene compound containing a fluorine atom. The first structural unit preferably contains 6 or more fluorine atoms.

### CROSS-REFERENCE TO RELATED APPLICATIONS

The present application is a continuation application of International Application No. PCT/JP2017/031678, filed Sep. 1, 2017, which claims priority to Japanese Patent Application No. 2016-172298, filed Sep. 2, 2016. The contents of these applications are incorporated herein by reference in their entirety.

### BACKGROUND OF THE INVENTION

### Field of the Invention

The present invention relates to a composition, a modification method and a selective modification method of a base material surface, as well as a pattern-forming method, and a polymer.

### Discussion of the Background

Further miniaturization of semiconductor devices has been accompanied by a demand for a technique of forming a fine pattern having a line width of less than 30 nm. However, it is technically difficult to meet such a demand by conventional methods employing lithography, due to optical factors and the like.

To this end, a bottom-up technique, as generally referred to, has been contemplated for forming a fine pattern. As the bottom-up technique, in addition to a method employing directed self-assembly of a polymer, a method for selectively modifying a base material having a surface layer that includes fine regions has been recently studied. The method for selectivity modifying the substrate requires a material enabling easy and highly selective modification of surface regions, and various materials have been investigated for such use (see Japanese Unexamined Patent Application, Publication No. 2016-25355; Japanese Unexamined Patent Application, Publication No. 2003-76036; ACS Nano, 9, 9, 8710, 2015; ACS Nano, 9, 9, 8651, 2015; Science, 318, 426, 2007; and Langmuir, 21, 8234, 2005).

### SUMMARY OF THE INVENTION

According to an aspect of the present invention, a composition includes a first polymer and a solvent. The first polymer includes a first structural unit including a fluorine atom, and a group including a first functional group at an end of a main chain or a side chain of the first polymer. The first functional group is capable of forming a bond with a metal or a metalloid.

According to another aspect of the present invention, a method for modifying a base material surface includes applying the composition on a surface of a base material to form a coating film, and heating the coating film. The base material includes a surface layer including a metal or a metalloid.

According to further aspect of the present invention, a method for selectively modifying a base material surface includes applying the composition on a surface of the base material to form a coating film. The base material includes a surface layer which includes a first region including a metal and a second region including a metalloid. The coating film is heated. A portion of the coating film, which is formed on at least one of the first region and the second region, is removed with a rinse agent.

According to further aspect of the present invention, a pattern-forming method includes applying the composition on a surface of the base material to form a coating film. The base material includes a surface layer which includes a first region including a metal and a second region including a metalloid. The coating film is heated. A portion of the coating film, which is formed on at least one of the first region and the second region, is removed with a rinse agent. A pattern is deposited on the surface of the base material after the removing, with a CVD method or an ALD method. The first polymer is etched away from the surface of the base material after the removing of the portion of the coating film.

According to further aspect of the present invention, a polymer includes a structural unit comprising a fluorine atom, and a group including a functional group at an end of a main chain or a side chain of the polymer. The functional group is capable of forming a bond with a metal or a metalloid.

### BRIEF DESCRIPTION OF THE DRAWINGS

FIG. 1 is a cross sectional view illustrating a substrate for use in producing a striped substrate.

FIG. 2 is a cross sectional view illustrating a cross sectional view of a striped substrate used for evaluation of selective surface modification.

### DESCRIPTION OF EMBODIMENTS

According to one embodiment of the invention, a composition comprises:

a first polymer comprising: a first structural unit comprising a fluorine atom; and at an end of a main chain or a side chain, a group comprising a first functional group capable of forming a bond with a metal or a metalloid; and

a solvent.

According to another embodiment of the invention, a method for modifying a base material surface comprises:

applying the composition of the one embodiment on a surface of a base material comprising a surface layer comprising a metal or a metalloid to form a coating film; and

heating the coating film.

According to other embodiment of the present invention, a method for selectively modifying a base material surface comprises:

providing a base material comprising a surface layer which comprises a first region comprising a metal and a second region comprising a metalloid;

applying the composition of the one embodiment on a surface of the base material to form a coating film;

heating the coating film; and

removing with a rinse agent a portion of the coating film, the portion being formed on at least one of the first region and the second region.

According to still other embodiment of the present invention, a pattern-forming method comprises:

providing a base material comprising a surface layer which comprises a first region comprising a metal and a second region comprising a metalloid;

applying the composition of the one embodiment on a surface of the base material to form a coating film;

heating the coating film; removing with a rinse agent a portion of the coating film, the portion being formed on at least one of the first region and the second region; and

depositing a pattern on the surface of the base material after the removing, with a CVD method or an ALD method.

According to yet other embodiment of the invention made for solving the aforementioned problems, a polymer comprises:

a structural unit comprising a fluorine atom; and

at an end of a main chain or a side chain, a group comprising a functional group capable of forming a bond with a metal or a metalloid.

The composition and the method for modifying a base material surface of the embodiments of the present invention enable water repellency to be sufficiently and continuously provided through modification of a surface region containing a metal or a metalloid. The method for selectively modifying a base material surface of the embodiment of the present invention enables sufficient and enduring water repellency to be selectively imparted to a base material surface. The pattern formation of the embodiment of the present invention enables a pattern having a favorable performance to be formed. The polymer of the embodiment of the present invention can be suitably used as a polymer component of the composition of the embodiment of the present invention. Therefore, these can be suitably used for working processes of semiconductor devices, and the like, in which microfabrication is expected be further in progress hereafter.

Hereinafter, embodiments of the composition and the method for modifying a base material surface will be described in detail.

### Composition

The composition of the embodiment of the invention contains:

a first polymer (hereinafter, may be also referred to as “(A) polymer” or “polymer (A)”) having: a first structural unit containing a fluorine atom (hereinafter, may be also referred to as “structural unit (I)”); and at an end of a main chain or a side chain, a group (hereinafter, may be also referred to as “group (I)”) containing a first functional group capable of forming a bond with a metal or a metalloid (hereinafter, may be also referred to as “functional group (A)”); and

a solvent (hereinafter, may be also referred to as “(B) solvent” or “solvent (B)”).

The composition may also contain other component(s) in addition to the polymer (A) and the solvent (B).

The composition is capable of sufficiently and continuously providing water repellency through modification of a surface region containing a metal or a metalloid. Furthermore, the surface region modified containing a metal or a metalloid is prevented from oxidization of the surface due to the polymer (A) containing a fluorine atom. Each component will be described below.

Polymer (A)

The polymer (A) has: the structural unit (I); and at an end of a main chain or a side chain, the group (I). The term “main chain” as referred to herein means the longest atom chain of atom chains in the polymer (A). The term “side chain” as referred to herein means atom chains other than the main chain in the polymer (A). In light of a possible increase in the density of the polymer (A) in the modification of the base material surface, the polymer (A) has the group (I) preferably at the end of the main chain, and more preferably at one end of the main chain.

The polymer (A) may further have a second structural unit (hereinafter, may be also referred to as “structural unit (II)”) which is a structural unit other than the structural unit (I) and is derived from substituted or unsubstituted styrene, as well as other structural unit except for the structural unit (I) and the structural unit (II). The polymer (A) may have one, or two or more types of these structural units. In a case in which the polymer (A) has a plurality of types of the structural units, each of these structural units may be arranged either block wise, or randomly. In other words, the polymer (A) may be either a block copolymer or a random copolymer, and is preferably a random copolymer. Each structural unit will be described below.

Structural Unit (I)

The structural unit (I) is a structural unit containing a fluorine atom.

The lower limit of the number of fluorine atoms in the structural unit (I) is, in light of a more improvement of water repellency of the modified region, preferably 3, more preferably 6, still more preferably 9, and particularly preferably 12. The upper limit of the number of fluorine atoms is preferably 20, and more preferably 18.

The form of the fluorine atom included in the structural unit (I) is exemplified by an organic group, etc., containing a fluorine atom. The term “organic group” as referred to herein means a group containing at least one carbon atom. The organic group containing a fluorine atom may be, for example, a monovalent group, a divalent group, or the like.

The lower limit of the number of carbon atoms in the organic group containing a fluorine atom is preferably 1, more preferably 3, still more preferably 5, and particularly preferably 6. The upper limit of the number of carbon atoms in the organic group containing a fluorine atom is preferably 20, more preferably 15, still more preferably 10, and particularly preferably 8.

The organic group containing a fluorine atom is exemplified by a fluorinated hydrocarbon group, and the like.

Exemplary fluorinated hydrocarbon group includes a fluorinated chain hydrocarbon group, a fluorinated alicyclic hydrocarbon group, a fluorinated aromatic hydrocarbon group, and the like.

Examples of a monovalent fluorinated chain hydrocarbon group include:

fluorinated alkyl groups such as a trifluoromethyl group, a trifluoroethyl group, a pentafluoroethyl group, a hexafluoropropyl group, a heptafluoropropyl group, a nonafluorobutyl group, an undecafluoropentyl group, a tridecafluorohexyl group, a pentadecafluoroheptyl group, a heptadecafluorooctyl group, a nonadecafluorononyl group and a henicosadecyl group;

fluorinated alkenyl groups such as a trifluoroethenyl group and a pentafluoropropenyl group;

fluorinated alkynyl groups such as a fluoroethynyl group and a trifluoropropynyl group; and the like.

Examples of a monovalent fluorinated alicyclic hydrocarbon group include:

fluorinated alicyclic saturated hydrocarbon groups such as a nonafluorocyclopentyl group and an undecafluorocyclohexyl group;

fluorinated alicyclic unsaturated hydrocarbon groups such as a heptafluorocyclopentenyl group and a nonafluorocyclohexenyl group; and the like.

Examples of a monovalent fluorinated aromatic hydrocarbon group include:

fluorinated aryl groups such as a fluorophenyl group, a trifluorophenyl group, a pentafluorophenyl group, a trifluoromethylphenyl group, a di(trifluoromethyl)phenyl group and a fluoronaphthyl group;

fluorinated aralkyl groups such as a fluorophenylmethyl group and a phenyldifluoromethyl group; and the like.

Of these, the fluorinated chain hydrocarbon group and the fluorinated aromatic hydrocarbon group are preferred, the fluorinated alkyl group and the fluorinated aryl group are more preferred, the fluorinated alkyl group having 6 to 8 carbon atoms and the fluorinated aryl group having 6 to 8 carbon atoms are still more preferred, and a tridecafluorohexyl group and a di(trifluoromethyl)phenyl group are particularly preferred.

The structural unit (I) is exemplified by a structural unit derived from: a (meth)acrylic ester containing a fluorine atom; a styrene compound, etc., containing a fluorine atom; and the like.

Examples of the (meth)acrylic ester containing a fluorine atom include (meth)acrylic esters containing a fluorinated chain hydrocarbon group, such as tridecafluorooctyl (meth)acrylate and heptadecafluorooctyl (meth)acrylate, and the like.

Examples of the styrene compound containing a fluorine atom include styrene compounds including a fluorinated aromatic hydrocarbon group, such as 3,5-di(trifluoromethyl)styrene, pentafluorostyrene and the like.

Of these, tridecafluorooctyl(meth)acrylate and 3,5-di(trifluoromethyl)styrene are preferred.

The lower limit of the proportion of the structural unit (I) contained with respect to the total structural units constituting the polymer (A) is preferably 10 mol %, more preferably 30 mol %, and still more preferably 40 mol %. The upper limit of the proportion of the structural unit (I) is preferably 100 mol %, more preferably 70 mol %, and still more preferably 50 mol %.

Structural Unit (II)

The structural unit (II) is a structural unit being other than the structural unit (I) and being derived from substituted or unsubstituted styrene.

Examples of the substituted styrene include α-methylstyrene, o-, m- or p-methylstyrene, p-tert-butylstyrene, 2,4,6-trimethylstyrene, p-methoxystyrene, p-tert-butoxystyrene, o-, m- or p-vinylstyrene, o-, m- or p-hydroxystyrene, m- or p-chloromethylstyrene, p-chlorostyrene, p-bromostyrene, p-iodostyrene, p-nitrostyrene, p-cyanostyrene, and the like.

The structural unit (II) is preferably a structural unit derived from unsubstituted styrene, tert-butylstyrene, tert-butoxystyrene or hydroxystyrene.

In a case in which the polymer (A) has the structural unit (II), the lower limit of the proportion of the structural unit (II) contained is preferably 5 mol %, more preferably 30 mol %, and still more preferably 45 mol %. The upper limit of the proportion of the structural unit (II) contained is preferably 80 mol %, more preferably 70 mol %, and still more preferably 60 mol %.

Other Structural Unit

The other structural unit is exemplified by a structural unit being other than the structural unit (I), and being derived from a (meth)acrylic ester or derived from substituted or unsubstituted ethylene, and the like.

Examples of the (meth)acrylic acid ester include:

(meth)acrylic acid alkyl esters such as methyl (meth)acrylate, ethyl (meth)acrylate, t-butyl (meth)acrylate and 2-ethylhexyl (meth)acrylate;

(meth)acrylic acid cycloalkyl esters such as cyclopentyl (meth)acrylate, cyclohexyl (meth)acrylate, 1-methylcyclopentyl (meth)acrylate, 2-ethyladamantyl (meth)acrylate and 2-(adamantan-1-yl)propyl (meth)acrylate;

(meth)acrylic acid aryl esters such as phenyl (meth)acrylate and naphthyl (meth)acrylate;

(meth)acrylic acid substituted alkyl esters such as 2-hydroxyethyl (meth)acrylate, 3-hydroxyadamantyl (meth)acrylate, 3-glycidylpropyl (meth)acrylate and 3-trimethylsilylpropyl (meth)acrylate; and the like.

Examples of the substituted ethylene include:

alkenes such as propene, butene and pentene;

vinylcycloalkanes such as vinylcyclopentane and vinylcyclohexane;

cycloalkenes such as cyclopentene and cyclohexene;

4-hydroxy-1-butene, vinyl glycidyl ether, vinyl trimethylsilyl ether, and the like.

In a case in which the polymer (A) has the other structural unit, the upper limit of the proportion of the other structural unit contained is preferably 30 mol %, and more preferably 10 mol %.

Group (I)

The group (I) contains a functional group (A) capable of forming a bond with a metal or a metalloid.

The metal is not particularly limited as long as it is a metal element, and examples of the metal include copper, iron, zinc, cobalt, aluminum, titanium, tin, tungsten, tantalum, zirconium, molybdenum, gold, silver, platinum, palladium, nickel, and the like. Of these, copper, cobalt, tungsten and tantalum are preferred.

The metalloid is not particularly limited as long as it is a metalloid element, and examples of the metalloid include silicon, germanium, and the like. Of these, silicon is preferred.

The form of the metal contained is exemplified by a metal simple substance, an alloy, an oxide, a nitride, a silicide, and the like.

Examples of the metal simple substance include simple substances of metals such as copper, iron, cobalt, tungsten and tantalum, and the like.

Examples of the alloy include a nickel-copper alloy, a cobalt-nickel alloy, a gold-silver alloy, and the like.

Examples of the oxide include tantalum oxide, aluminum oxide, iron oxide, copper oxide, zinc oxide, zirconium oxide, and the like.

Examples of the nitride include tantalum nitride, titanium nitride, iron nitride, aluminum nitride, gallium nitride, and the like.

Examples of the silicide include iron silicide, molybdenum silicide, and the like. Of these, the metal simple substance and the nitride are preferred, and a copper simple substance, a cobalt simple substance, a tungsten simple substance, a tantalum simple substance and a tantalum nitride are more preferred.

The form of the metalloid contained is exemplified by a metalloid simple substance, an oxide, a nitride, an oxynitride, and the like.

Examples of the metalloid simple substance include simple substances of metalloids such as silicon and germanium, and the like.

Examples of the oxide include silicon oxide, germanium oxide, and the like.

Examples of the nitride include SiNₓ, Si₃N₄ and SiCN.

Examples of the oxynitride include SiON, and the like. Of these, the oxide is preferred, and silicon oxide is more preferred.

The bond is exemplified by a chemical bond, and examples of the bond include a covalent bond, an ionic bond, a coordinate bond, a hydrogen bond, and the like. Of these, the bond between the metal and the functional group (A) is preferably a coordinate bond. The bond between the metalloid and the functional group (A) is preferably a covalent bond or a hydrogen bond.

Examples of the functional group (A) include:

a sulfanyl group;

hydroxy groups such as an alcoholic hydroxy group and a phenolic hydroxy group;

a carboxy group;

a cyano group;

ethylenic carbon-carbon double bond-containing groups such as a vinyl group, an allyl group, a styryl group and a (meth)acryloyl group;

nitrogen-containing hetero ring-containing groups, e.g., oxazoline ring-containing groups such as an oxazolyl group and an isooxazolyl group, pyridine ring-containing groups such as a pyridyl group, a quinolyl group and an isoquinolyl group, imidazole ring-containing groups such as an imidazolyl group and a quinazolyl group, as well as nitrogen atom-containing groups such as an amidino group (—C(═NH)—NH₂);

phosphorus atom-containing groups such as a phosphoric acid group, a phosphonic acid group (—P(═O)(OH)₂) and a phosphinic acid group (—P(═O)OH);

epoxy groups such as an oxiranyl group and an oxetanyl group;

a disulfide group (—S—S—);

alkoxysilyl groups such as a trimethoxysilyl group and a methyldimethoxysilyl group;

silanol groups such as a hydroxydimethoxysilyl group and a hydroxymethylmethoxysilyl group; and the like.

Of these, the functional group (A) bonded to the metal is preferably a sulfanyl group, the hydroxy group, a carboxy group, a cyano group, the ethylenic carbon-carbon double bond-containing group, the nitrogen atom-containing group, the phosphorus atom-containing group, the epoxy group or a disulfide group. The functional group (A) bonded to the metalloid is preferably the alkoxysilyl group or the silanol group.

The lower limit of the number average molecular weight (Mn) of the polymer (A) is preferably 500, more preferably 2,000, still more preferably 3,000, and particularly preferably 4,000. The upper limit of the Mn of the polymer (A) is preferably 50,000, more preferably 30,000, still more preferably 15,000, and particularly preferably 8,000.

The upper limit of the ratio (Mw/Mn: dispersity index) of the weight average molecular weight (Mw) to the Mn of the polymer (A) is preferably 5, 2, more preferably 1.7, and particularly preferably 1.4. The lower limit of the ratio is typically 1, and preferably 1.1.

The lower limit of the content of the polymer (A) in the composition (I) with respect to the total solid content is preferably 80% by mass, more preferably 90% by mass, and still more preferably 95% by mass. The upper limit of the content is, for example, 100% by mass. The “total solid content” as referred to herein means the sum of the components other than the solvent (B).

Synthesis Method of Polymer (A)

The polymer (A) may be synthesized by, for example: allowing for reversible addition fragmentation chain transfer (RAFT) polymerization using a monomer that gives the structural unit (I), etc., and a compound (reversible addition fragmentation chain transfer agent) such as methyl 4-cyano-4-[(dodecylsulfanylthiocarbonyl)sulfanyl]pentanoate in the presence of a polymerization initiator such as azobisisobutyronitrile, in a solvent such as anisole; and adding to a resultant polymer, a primary amine such as n-butylamine, and water or an alcohol such as methanol to carry out an amine decomposition reaction, thereby introducing a thiol (—SH) end to the polymer. Alternatively, a polymer to which a nitrile group was introduced at an end can be synthesized through allowing for an azo decomposition reaction by adding an excessively large amount of an azo initiator such as azobisisobutyronitrile (AIBN) to the polymer obtained by the RAFT polymerization described above.

(B) Solvent

The solvent (B) is not particularly limited as long as it is a solvent capable of dissolving or dispersing at least the polymer (A) and other component(s).

The solvent (B) is exemplified by an alcohol solvent, an ether solvent, a ketone solvent, an amide solvent, an ester solvent, a hydrocarbon solvent, and the like.

Examples of the alcohol solvent include:

aliphatic monohydric alcohol solvents having 1 to 18 carbon atoms such as 4-methyl-2-pentanol and n-hexanol;

alicyclic monohydric alcohol solvents having 3 to 18 carbon atoms such as cyclohexanol;

polyhydric alcohol solvent having 2 to 18 carbon atoms such as 1,2-propylene glycol;

polyhydric alcohol partially etherated solvents having 3 to 19 carbon atoms such as propylene glycol monomethyl ether; and the like.

Examples of the ether solvent include:

dialkyl ether solvents such as diethyl ether, dipropyl ether, dibutyl ether, dipentyl ether, diisoamyl ether, dihexyl ether and diheptyl ether;

cyclic ether solvents such as tetrahydrofuran and tetrahydropyran;

aromatic ring-containing ether solvents such as diphenyl ether and anisole (methyl phenyl ether); and the like.

Examples of the ketone solvent include:

chain ketone solvents such as acetone, methyl ethyl ketone, methyl n-propyl ketone, methyl n-butyl ketone, diethyl ketone, methyl iso-butyl ketone, 2-heptanone (methyl-n-pentyl ketone), ethyl n-butyl ketone, methyl n-hexyl ketone, di-iso-butyl ketone and trimethylnonanone;

cyclic ketone solvents such as cyclopentanone, cyclohexanone, cycloheptanone, cyclooctanone and methylcyclohexanone;

2,4-pentanedione, acetonylacetone, and acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methylacetamide, N,N-dimethylacetamide and N-methylpropionamide; and the like.

Examples of the ester solvent include:

monocarboxylic acid ester solvents such as n-butyl acetate and ethyl lactate;

polyhydric alcohol carboxylate solvents such as propylene glycol acetate;

polyhydric alcohol partially etherated carboxylate solvents such as propylene glycol monomethyl ether acetate;

lactone solvents such as γ-butyrolactone and δ-valerolactone;

polyhydric carboxylic acid diester solvents such as diethyl oxalate;

carbonate solvents such as dimethyl carbonate, diethyl carbonate, ethylene carbonate and propylene carbonate; and the like.

Examples of the hydrocarbon solvent include:

aliphatic hydrocarbon solvents such as n-pentane, iso-pentane, n-hexane, iso-hexane, n-heptane, iso-heptane, 2,2,4-trimethylpentane, n-octane, iso-octane, cyclohexane and methylcyclohexane;

aromatic hydrocarbon solvents such as benzene, toluene, xylene, mesitylene, ethylbenzene, trimethylbenzene, methylethylbenzene, n-propylbenzene, iso-propylbenzene, diethylbenzene, iso-butylbenzene, triethylbenzene, di-iso-propylbenzene and n-amylnaphthalene; and the like.

Examples of the fluorine solvent include: fluorine atom-containing alcohol solvents such as trifluoroethanol, pentafluoropropanol, heptafluorobutanol, bis(trifluoromethyl)propanol, octafluoropentanol, decafluorohexanol, dodecafluoroheptanol, perfluoroethylhexanol, octafluorohexanediol and dodecafluorooctanediol; and the like.

Of these, the ester solvent and the fluorine solvent are preferred, the polyhydric alcohol partially etherated carboxylate solvent and the fluorine atom-containing alcohol solvent are more preferred, and propylene glycol monomethyl ether acetate and octafluoropentanol are still more preferred. One, or two or more types of the solvent (B) may be used.

Optional Component

The composition of the embodiment of the present invention may also contain other component(s) in addition to the polymer (A) and the solvent (B). The other component(s) is/are exemplified by a surfactant and the like. When the composition contains the surfactant, the application property onto the base material surface may be improved.

Preparation Method of Composition

The composition may be prepared by, for example, mixing the polymer (A), the solvent (B), and as needed the optional component(s) at a predetermined ratio, and preferably filtering the resulting mixture through a high-density polyethylene filter, etc., having fine pores of about 0.45 μm, etc. The lower limit of the solid content concentration of the composition is preferably 0.1% by mass, more preferably 0.5% by mass, still more preferably 0.7% by mass, and particularly preferably 1.0% by mass. The upper limit of the solid content concentration is preferably 30% by mass, more preferably 10% by mass, still more preferably 5% by mass, and particularly preferably 2% by mass.

The composition can be suitably used for, e.g., modification and selective modification of a surface of a base material containing a metal or a metalloid on a surface layer thereof, as well as pattern formation, and the like.

### Method for Modifying Base Material Surface

The method for modifying a base material surface (i.e., modification method of a base material surface) of the embodiment of the present invention includes: a step of applying the composition of the embodiment of the invention on a surface of a base material containing a metal or a metalloid on a surface layer to form a coating film (hereinafter, may be also referred to as “applying step”); and a step of heating the coating film formed by the applying step (hereinafter, may be also referred to as “heating step”). Each step of the method for modifying a base material surface will be described below.

Applying Step

In this step, the composition of the embodiment of the invention is applied on a surface of a base material containing a metal or a metalloid on a surface layer to form a coating film.

Examples of the metal and the metalloid include those exemplified as the element and the form thereof contained, to which the functional group (A) bonds in the group (I) of the polymer (A), and the like.

On the surface layer of the base material, there exist a region containing the metal, a region containing the metalloid, and the like. A mode of the arrangement of these regions on the surface layer of the base material is not particularly limited, and is exemplified by surficial, spotted, striped, and the like in a planar view. The size of these regions is not particularly limited, and may be an appropriately desired size.

The shape of the base material is not particularly limited, and may be an appropriately desired shape such as platy (substrate), spherical, and the like.

Application procedure of the composition is exemplified by a spin-coating method, and the like.

Heating Step

In this step, the coating film formed by the applying step is heated. Accordingly, formation of the bond between the metal or a metalloid on the surface layer of the base material and the functional group (A) in the polymer (A) of the composition is accelerated, whereby a coating film (hereinafter, may be also referred to as “coating film (I)”) containing the polymer (A) is overlaid on the base material surface.

Means for heating may be, for example, an oven, a hot plate, and the like. The lower limit of the heating temperature is preferably 80° C., more preferably 100° C., and still more preferably 130° C. The upper limit of the heating temperature is preferably 400° C., more preferably 300° C., and still more preferably 200° C. The lower limit of the heating time period is preferably 10 sec, more preferably 1 min, and still more preferably 2 min. The upper limit of the heating time period is preferably 120 min, more preferably 10 min, and still more preferably 5 min.

### Method for Selectively Modifying Base Material Surface

The method for selectively modifying a base material surface (i.e., selective modification method of a base material surface) of the embodiment of the present invention includes: a step of providing a base material including on a surface layer a first region containing a metal (hereinafter, may be also referred to as “region (I)”) and a second region containing a metalloid (hereinafter, may be also referred to as “region (II)”) (hereinafter, may be also referred to as “providing step”); a step of applying the composition of the embodiment of the invention on a surface of the base material to form a coating film (hereinafter, may be also referred to as “applying step”); a step of heating the coating film formed by the applying step (hereinafter, may be also referred to as “heating step”); and a step of removing with a rinse agent a portion of the coating film, the portion being formed on at least one of the first region and the second region (hereinafter, may be also referred to as “removing step”). It is to be noted that the applying step and heating step may be carried out in a similar manner to those in the modification method described above. It is preferred that the selective modification method further includes a step of bringing an alcohol, a dilute acid, a hydrogen peroxide solution, ozone or plasma into contact with the surface of the base material after the removing step (contacting step). In addition, the method for selectively modifying a base material surface may further include steps described later, for example, a step of bringing an alcohol, a dilute acid, a hydrogen peroxide solution, ozone or plasma into contact with the surface of the base material after the removing step (hereinafter, may be also referred to as “contacting step”), a step of depositing a pattern on the surface of the base material after the removing step, with a CVD method or an ALD method (hereinafter, may be also referred to as “depositing step”), a step of etching away the polymer (A) from the surface of the base material after the removing step (hereinafter, may be also referred to as “etching step”), and the like.

Providing Step

In this step, a base material including on the surface layer, a region containing the metal (I), and a region containing the metalloid (II) is provided.

The metal and the metalloid, and the form of the same are similar to those in the method for modifying a base material surface described above, and the shape of the base material is also similar to those in the method for modifying a base material surface described above.

Removing Step

In this step, of the polymer (A), a portion not forming a bond to the metal or the metalloid is removed. Accordingly, a portion including the polymer (A) not bonded to the metal or the metalloid after the heating step is removed, whereby a base material having a portion of the region containing the metal or the metalloid being selectively modified is obtained.

The removing in the removing step is carried out typically by rinsing the base material after the heating step with a rinse agent. The rinse agent used is typically an organic solvent, and for example, a polyhydric alcohol partially etherated carboxylate solvent such as propylene glycol monomethyl ether acetate, a monohydric alcohol solvent such as isopropanol, or the like may be used.

The average thickness of the coating film (I) formed can be adjusted to a desired value through appropriately selecting the type and concentration of the polymer (A) in the composition, and conditions in the heating step such as the heating temperature and the heating time period. The lower limit of the average thickness of the coating film (I) is preferably 0.1 nm, more preferably 1 nm, and still more preferably 3 nm. The upper limit of the average thickness is, for example, 20 nm.

In the aforementioned manner, simple and highly selective modification of the surface region containing a metal or a metalloid is enabled. Thus obtained base material may be variously processed by carrying out, for example, the following step(s).

Contacting Step

In this step, an alcohol, a dilute acid, a hydrogen peroxide solution, ozone or plasma is brought into contact with the surface of the base material after the removing step. Accordingly, an air-oxidized film layer formed on a region other than the region containing the metal or the metalloid can be removed. The dilute acid is not particularly limit, and examples of the dilute acid include dilute hydrochloric acid, dilute sulfuric acid, dilute nitric acid, and the like.

Etching Step

In this step which may be further included, the polymer (A) on the surface of the base material after the removing step etched away (etching step). For example, after forming a pattern on the surface of the base material in the depositing step, removing of the polymer (A) by the etching step enables a pattern having a predetermined shape such as stripe to be formed on the substrate.

The etching procedure is exemplified by well-known techniques including: reactive ion etching (RIE) such as chemical dry etching carried out using CF₄, an O₂ gas or the like by utilizing the difference in etching rate of each layer, etc., as well as chemical wet etching (wet development) carried out by using an etching liquid such as an organic solvent or hydrofluoric acid; physical etching such as sputtering etching and ion beam etching. Of these, the reactive ion etching is preferred, and the chemical dry etching and the chemical wet etching are more preferred.

Prior to the chemical dry etching, an irradiation with a radioactive ray may be also carried out as needed. As the radioactive ray, when the portion to be etched away is a polymer that includes a methyl polymethacrylate block, ultraviolet light or the like may be used. The irradiation with such a radioactive ray results in degradation of the methyl polymethacrylate block phase, whereby the etching is facilitated.

Examples of the organic solvent for use in the chemical wet etching include:

alkanes such as n-pentane, n-hexane and n-heptane;

cycloalkanes such as cyclohexane, cycloheptane and cyclooctane;

saturated carboxylic acid esters such as ethyl acetate, n-butyl acetate, i-butyl acetate and methyl propionate;

ketones such as acetone, methyl ethyl ketone, methyl isobutyl ketone and methyl n-pentyl ketone;

alcohols such as methanol, ethanol, 1-propanol, 2-propanol and 4-methyl-2-pentanol; and the like. These solvents may be used either alone, or two or more types thereof may be used in combination.

### Pattern-Forming Method

The pattern-forming method of the embodiment of the present invention includes: a step of providing a base material including on a surface layer a first region containing a metal (region (I)) and a second region containing a metalloid (region (II)) (providing step); a step of applying the composition of the embodiment of the invention on a surface of the base material to form a coating film (applying step); a step of heating the coating film formed by the applying step (heating step); a step of removing with a rinse agent a portion of the coating film, the portion being formed on at least one of the first region and the second region (removing step); and a step of depositing a pattern on the surface of the base material after the removing, with a CVD method or an ALD method (depositing step), whereby formation of a pattern having a predetermined shape on the substrate is enabled.

Depositing Step

In this step, the pattern is deposited on the surface of the base material after the removing step by a CVD (chemical vapor deposition) method or an ALD (atom layer depositing) method. Thus, the pattern can be formed selectively on the region not covered by the polymer (A).

Examples of the material for the pattern to be deposited by the ALD method include metal oxides such as aluminum oxide, zinc oxide and zirconium oxide, and the like.

### EXAMPLES

Hereinafter, the present invention is explained in detail by way of Examples, but the present invention is not in any way limited to these Examples. Measuring method for each physical property is shown below.

Mw and Mn

The Mw and the Mn of the polymer were determined by gel permeation chromatography (GPC) using GPC columns (Tosoh Corporation; “G2000 HXL” ×2, “G3000 HXL” ×1 and “G4000 HXL” ×1) under the following conditions:

eluent: tetrahydrofuran (Wako Pure Chemical Industries, Ltd.);

flow rate: 1.0 mL/min;

sample concentration: 1.0% by mass;

amount of sample injected: 100 μL;

column temperature: 40° C.;

detector: differential refractometer; and

standard substance: mono-dispersed polystyrene.

¹³C-NMR Analysis

¹³C-NMR analysis was carried out using a nuclear magnetic resonance apparatus (“JNM-EX400” available from JEOL, Ltd.), with DMSO-d₆ for use as a solvent for measurement. The proportion of each structural unit in the polymer was calculated from an area ratio of a peak corresponding to each structural unit on the spectrum obtained by the ¹³C-NMR.

### Preparation of 4-nonafluorobutylacetophenone

In a 200 mL three-neck flask equipped with a condenser, 22.0 g of 4-bromoacetophenone (110.4 mmol), 41.74 g of nonafluorobutyliodide (119.6 mmol), 100 g of dimethylsulfoxide, and 14.0 g of copper (zero valent) powder (two equivalents with respect to 4-bromoacetophenone) were heated with stirring at 110° C. for 20 hrs in a nitrogen atmosphere. After completion of the reaction, the entirety was transferred into a 1,000 mL plastic beaker, to which 150 g of methyl isobutyl ketone and 150 g of ultra pure water were gradually added. The mixture was stirred to be vigorously in contact with the air at a normal temperature for 1 hr, whereby copper oxide was deposited, and the mixture was filtered through a Buechner funnel to separate copper oxide from the filtrate, which was collected. The filtrate was washed with water by using a separatory funnel to remove dimethylsulfoxide, whereby the organic layer was collected. A solution obtained by dehydrating the organic layer over magnesium sulfate and filtering was concentrated in vacuo. Vacuum distillation of the liquid after the concentration gave 26.5 g of an intended product (yield; 79%), with a fraction at a boiling point of 80° C./20 Pa as a main fraction.

GC-MASS m/z; 338

¹H-NMR (CDCl₃); 8.05 (2H, m-Ph), 7.66 (2H, o-Ph), 2.53 (3H, CH₃).

### Preparation of 4-nonafluorobutylphenylethanol

In a 200 mL three-neck flask equipped with a condenser and a dropping funnel, 20 g of 4-nonafluorobutylacetophenone (59 mmol) and 30 g of dry diethyl ether were added dropwise to 2.60 g of lithium hydride aluminum (68.8 mmol) and 30 g of diethyl ether with a dropping funnel over 30 min under ice cooling in a nitrogen atmosphere. Next, the mixture was stirred for 2 hrs with the temperature being elevated to a normal temperature. After completion of the reaction, lithium hydride aluminum was slowly deactivated with aqueous trahydrofuran, methanol and ultra pure water under ice cooling. The solution layer was filtered to collect the filtrate. The filtrate was washed with a 1 N aqueous hydrochloric acid solution, and the organic layer was collected, which was dehydrated over magnesium sulfate and then filtered. The filtrate was concentrated in vacuo, and vacuum distillation of the obtained solution gave 17.6 g of an intended product (yield: 88%), with a fraction at a boiling point of 86° C./25 Pa as a main fraction.

GC-MASS m/z; 340.0

¹H-NMR (CDCl₃); 7.56 (2H, m-Ph), 7.36 (2H, o-Ph), 4.77 (1H, CH), 3.17 (1H, OH), 1.40 (3H, CH₃).

### Preparation of 4-nonafluorobutylstyrene

Into a 200 mL three-neck flask equipped with a condenser were added 15.3 g of 4-fluorobutylphenylethanol (45 mmol), 6 g of potassium hydrogen sulfate, 15 g of toluene and 0.02 g tert-butylcatechol in a nitrogen atmosphere, and the mixture was heated with stirring at 110° C. for 18 hrs. After thus obtained solution was filtered, toluene was concentrated in vacuo. Vacuum distillation of the solution after the concentration gave 9.6 g of an intended product (yield; 66%), with a fraction at a boiling point of 83° C./18 Pa fraction as a main fraction.

GC-MASS m/z; 322.0

¹H-NMR (CDCl₃); 7.62 (2H, m-Ph), 7.45 (2H, o-Ph), 6.49-6.97 (1H, ═CH), 5.93-5.24 (2H, ═CH₂)

### Preparation of 4-(1H,1H,2H,2H-nonafluorohexyl)styrene

In a 300 mL three-neck flask equipped with a condenser and a dropping funnel, a liquid prepared by diluting 12.7 mL of 4-chlorostyrene (106 mmol) in 10 mL of dry tetrahydrofuran was added dropwise to 3 g of Mg (zero valent) (111 mmol) and 100 mL of dry tetrahydrofuran with a dropping funnel in a nitrogen atmosphere to prepare a styryl-Grignard reagent. To this Grignard reagent, a liquid prepared by diluting 17.7 mL of 1H,1H,2H,2H-nonafluorohexyliodide (92 mmol) in 30 mL of dry tetrahydrofuran was added dropwise with a dropping funnel, and then heated at 50° C. with stirring. After completion of the reaction, the mixture was filtered to collect a filtrate, to which methyl ethyl ketone was added, followed by washing with water and then concentration in vacuo. Next, vacuum distillation gave 20 g of an intended product (yield; 54%), with a fraction at a boiling point of 90° C./25 Pa as a main fraction.

GC-MASS m/z; 350

¹H-NMR (CDCl₃); 7.62 (2H, m-Ph), 7.45 (2H, o-Ph), 6.49-6.97 (1H, ═CH), 5.93-5.24 (2H, ═CH₂), 3.71 (2H, CH₂—CF₂), 2.83 (2H, CH₂Ph)

### Preparation of 4-perfluoroisopropylacetophenone

In a 300 mL three-neck flask equipped with a condenser, 44.1 g of 4-bromoacetophenone (220.8 mmol), 78.1 g of heptafluoroisopropyl iodide (264 mmol), 120 g of dimethylsulfoxide, and 28.4 g of copper (zero valent) powder (two equivalents with respect to 4-bromoacetophenone) were heated with stirring at 110° C. for 20 hrs in a nitrogen atmosphere. After completion of the reaction, the entirety was transferred into a 1,000 mL plastic beaker, to which 150 g of methyl isobutyl ketone and 150 g of ultra pure water were gradually added. The mixture was stirred to be vigorously in contact with the air at a normal temperature for 1 hr, whereby copper oxide was deposited. The mixture was filtered through a Buechner funnel to separate into copper oxide and the filtrate that was then collected. The filtrate was washed with water by using a separatory funnel to remove dimethylsulfoxide, whereby the organic layer was collected. Thereafter, a solution obtained by dehydrating the organic layer over magnesium sulfate and filtering was concentrated in vacuo. Vacuum distillation of the liquid after the concentration gave 36.5 g of an intended product (yield; 58%), with a fraction at a boiling point of 76° C./20 Pa as a main fraction.

GC-MASS m/z; 288

¹H-NMR (CDCl₃); 8.12 (21-1, m-Ph), 7.76 (2H, o-Ph), 2.53 (3H, CH₃).

### Preparation of 4-perfluoroisopropylphenylethanol

In a 500 mL three-neck flask equipped with a condenser and a dropping funnel, 20 g of 4-perfluoroisopropylacetophenone (69.4 mmol) and 30 g of dry diethyl ether were added dropwise to 3.05 g of lithium hydride aluminum (80.5 mmol) and 100 g of diethyl ether with a dropping funnel over 30 min under ice cooling in a nitrogen atmosphere. Next, the mixture was stirred for 2 hrs with the temperature being elevated to a normal temperature. After completion of the reaction, lithium hydride aluminum was slowly deactivated with aqueous trahydrofuran, methanol and ultra pure water under ice cooling. The solution layer was filtered to collect the filtrate. The filtrate was washed with a 1 N aqueous hydrochloric acid solution, and the organic layer was collected, which was dehydrated over magnesium sulfate and then filtered. The filtrate was concentrated in vacuo, and vacuum distillation of the obtained solution gave 17.5 g of an intended product (yield; 88%), with a fraction at a boiling point of 75° C./25 Pa as a main fraction.

GC-MASS m/z; 290.0

¹H-NMR (CDCl₃); 7.54 (2H, m-Ph), 7.33 (2H, o-Ph), 4.67 (1H, CH), 3.15 (1H, OH), 1.40 (3H, CH₃).

### Preparation of 4-perfluoroisopropylstyrene

Into a 200 mL three-neck flask equipped with a condenser were added 13.1 g of 4-perfluoroisopropylphenylethanol (45 mmol), 6 g of potassium hydrogen sulfate, 15 g of toluene and 0.02 g tert-butylcatechol in a nitrogen atmosphere, and the mixture was heated with stirring at 110° C. for 18 hrs. After thus obtained solution was filtered, toluene was concentrated in vacuo. Vacuum distillation of the solution after the concentration gave 8.9 g of an intended product (yield; 73%), with a fraction at a boiling point of 73° C./20 Pa fraction as a main fraction.

GC-MASS m/z; 272.1

¹H-NMR (CDCl₃); 7.54 (2H, m-Ph), 7.33 (2H, o-Ph), 6.47-6.99 (1H, ═CH), 5.91-5.21 (2H, ═CH₂)

### Synthesis of Polymer (A)

### Synthesis Example 1

After a 200 mL three-neck flask as a reaction vessel was dried under reduced pressure, 20 g of anisole which had been subjected to a distillation dehydrating treatment was charged in a nitrogen atmosphere, and thereto were added 6.48 g of tridecafluorooctyl methacrylate (15 mmol), 0.42 g of methyl 4-cyano-4-[(dodecylsulfanylthiocarbonyl)sulfanyl]pentanoate (1 mmol) and 0.056 g of azobisisobutyronitrile (0.34 mmol), followed by cooling with dry ice/methanol and conducting a degassing operation ten times. Next, on an oil bath at 80° C., the mixture was heated with stirring in a nitrogen atmosphere for 8 hrs. After cooling, to the polymerization solution were added 1.2 g of n-butylamine (16 mmol), 10 g of tetrahydrofuran and 2 g of methanol, and the mixture was heated with stirring on an oil bath at 50° C. for 2 hrs, thereby allowing for amine decomposition of the reversible addition fragmentation chain transfer agent at the polymerization terminal chain. The color of thus resulting polymerization solution changed from yellow to colorless. Subsequently, the polymerization solution was added dropwise to a large amount of methanol, and a highly viscous solid matter was obtained through decantation. Thus obtained viscous substance was dried under reduced pressure, and further dissolved in octafluoropentanol to give a 10% by mass solution of a polymer (A-1). The polymer (A-1) had the Mw of 3,200, the Mn of 2,600, and the Mw/Mn of 1.23.

### Synthesis Example 2

After a 200 mL three-neck flask as a reaction vessel was dried under reduced pressure, 30 g of anisole which had been subjected to a distillation dehydrating treatment was charged in a nitrogen atmosphere, and thereto were added 5.83 g of tridecafluorooctyl methacrylate (13.5 mmol), 2.7 g of tert-butylstyrene (16.5 mmol), 0.83 g of methyl 4-cyano-4-[(dodecylsulfanylthiocarbonyl)sulfanyl]pentanoate (2 mmol) and 0.068 g of azobisisobutyronitrile (0.68 mmol), followed by cooling with dry ice/methanol and conducting a degassing operation ten times. Next, on an oil bath at 80° C., the mixture was heated with stirring in a nitrogen atmosphere for 8 hrs. After cooling, to the polymerization solution were added 2.4 g of n-butylamine (32 mmol), 10 g of tetrahydrofuran and 2 g of methanol, and the mixture was heated with stirring on an oil bath at 50° C. for 2 hrs, thereby allowing for amine decomposition of the reversible addition fragmentation chain transfer agent at the polymerization terminal chain. The color of thus resulting polymerization solution changed from yellow to colorless. Subsequently, the polymerization solution was added dropwise to a large amount of methanol, and a highly viscous solid matter was obtained through decantation. Thus obtained viscous substance was dried under reduced pressure, and further dissolved in propylene glycol monomethyl ether acetate to give a 10% by mass solution of a polymer (A-2). The polymer (A-2) had the Mw of 3,300, the Mn of 2,600, and the Mw/Mn of 1.27.

### Synthesis Example 3

After a 200 mL three-neck flask as a reaction vessel was dried under reduced pressure, 20 g of anisole which had been subjected to a distillation dehydrating treatment was charged in a nitrogen atmosphere, and thereto were added 5.00 g of 3,5-di(trifluoromethyl)styrene (21 mmol), 0.44 g of methyl 4-cyano-4-[(dodecylsulfanylthiocarbonyl)sulfanyl]pentanoate (1.05 mmol) and 0.057 g of azobisisobutyronitrile (0.35 mmol), followed by cooling with dry ice/methanol and conducting a degassing operation ten times. Next, on an oil bath at 80° C., the mixture was heated with stirring in a nitrogen atmosphere for 8 hrs. After cooling, to the polymerization solution were added 1.2 g of n-butylamine (16 mmol), 10 g of tetrahydrofuran and 2 g of methanol, and the mixture was heated with stirring on an oil bath at 70° C. for 2 hrs, thereby allowing for amine decomposition of the reversible addition fragmentation chain transfer agent at the polymerization terminal chain. The color of thus resulting polymerization solution changed from yellow to colorless. Subsequently, the polymerization solution was added dropwise to a large amount of ultra pure water/methanol (mass ratio: 1/1), and a highly viscous solid matter was obtained through decantation. Thus obtained viscous substance was dried under reduced pressure, and further dissolved in propylene glycol monomethyl ether acetate to give a 10% by mass solution of a polymer (A-3). The polymer (A-3) had the Mw of 6,100, the Mn of 5,000, and the Mw/Mn of 1.22.

### Synthesis Example 4

After a 200 mL three-neck flask as a reaction vessel was dried under reduced pressure, 30 g of anisole which had been subjected to a distillation dehydrating treatment was charged in a nitrogen atmosphere, and thereto were added 5.83 g of tridecafluorooctyl methacrylate (13.5 mmol), 1.84 g of tert-butylstyrene (11.5 mmol), 0.81 g of 4-acetoxy styrene (5 mmol), 0.83 g of methyl 4-cyano-4-[(dodecylsulfanylthiocarbonyOsulfanyl]pentanoate (2 mmol) and 0.068 g of azobisisobutyronitrile (0.68 mmol), followed by cooling with dry ice/methanol and conducting a degassing operation ten times. Next, on an oil bath at 80° C., the mixture was heated with stirring in a nitrogen atmosphere for 8 hrs. After cooling, to the polymerization solution were added 5.05 g of triethylamine (50 mmol), 10 g of tetrahydrofuran and 5 g of propylene glycol monomethyl ether to carry out a hydrolysis reaction under reflux at 80° C. for 6 hrs. Next, 2.4 g of n-butylamine (32 mmol) and 2 g of methanol were added to the reaction mixture, and the mixture was heated with stirring on an oil bath at 50° C. for 2 hrs, thereby allowing for amine decomposition of the reversible addition fragmentation chain transfer agent at the polymerization terminal chain. The color of thus resulting polymerization solution changed from yellow to colorless. Subsequently, the polymerization solution was added dropwise to a large amount of methanol, and a highly viscous solid matter was obtained through decantation. Thus obtained viscous substance was dried under reduced pressure, and further dissolved in propylene glycol monomethyl ether acetate to give a 10% by mass solution of a polymer (A-4). The polymer (A-4) had the Mw of 3,600, the Mn of 2,850, and the Mw/Mn of 1.26.

### Synthesis Example 5

After a 200 mL three-neck flask as a reaction vessel was dried under reduced pressure, 30 g of anisole which had been subjected to a distillation dehydrating treatment was charged in a nitrogen atmosphere, and thereto were added 5.83 g of tridecafluorooctyl methacrylate (13.5 mmol), 2.40 g of tert-butylstyrene (15.0 mmol), 0.26 g of 4-tert-butoxystyrene (1.5 mmol), 0.83 g of methyl 4-cyano-4-[(dodecylsulfanylthiocarbonyl)sulfanyl]pentanoate (2 mmol) and 0.068 g of azobisisobutyronitrile (0.68 mmol), followed by cooling with dry ice/methanol and conducting a degassing operation ten times. Next, on an oil bath at 80° C., the mixture was heated with stirring in a nitrogen atmosphere for 8 hrs. After cooling, to the polymerization solution were added 2.4 g of n-butylamine (32 mmol), 10 g of tetrahydrofuran and 2 g of methanol, and the mixture was heated with stirring on an oil bath at 50° C. for 2 hrs, thereby allowing for amine decomposition of the reversible addition fragmentation chain transfer agent at the polymerization terminal chain. The color of thus resulting polymerization solution changed from yellow to colorless. Subsequently, the polymerization solution was added dropwise to a large amount of methanol, and a highly viscous solid matter was obtained through decantation. Thus obtained viscous substance was dried under reduced pressure, and further dissolved in propylene glycol monomethyl ether acetate to give a 10% by mass solution of a polymer (A-5). The polymer (A-5) had the Mw of 5,100, the Mn of 4,800, and the Mw/Mn of 1.29.

### Synthesis Example 6

After a 200 mL three-neck flask as a reaction vessel was dried under reduced pressure, 30 g of anisole which had been subjected to a distillation dehydrating treatment was charged in a nitrogen atmosphere, and thereto were added 5.83 g of tridecafluorooctyl methacrylate (13.5 mmol), 2.7 g of tert-butylstyrene (16.5 mmol), 0.83 g of methyl 4-cyano-4-[(dodecylsulfanylthiocarbonyl)sulfanyl]pentanoate (2 mmol) and 0.068 g of azobisisobutyronitrile (0.68 mmol), followed by cooling with dry ice/methanol and conducting a degassing operation ten times. Next, on an oil bath at 80° C., the mixture was heated with stirring in a nitrogen atmosphere for 8 hrs. After cooling, to the polymerization solution were added 3.28 g of azoisobutyronitrile (20.0 mmol) and 10 g of tetrahydrofuran, and the mixture was heated with stirring on an oil bath at 80° C. for 6 hrs, thereby allowing for azo decomposition of the reversible addition fragmentation chain transfer agent at the polymerization terminal chain. Subsequently, the polymerization solution was added dropwise to a large amount of methanol, and a highly viscous solid matter was obtained through decantation. Thus obtained viscous substance was dried under reduced pressure, and further dissolved in propylene glycol monomethyl ether acetate to give a 10% by mass solution of a polymer (A-6). The polymer (A-6) had the Mw of 3,600, the Mn of 2,800, and the Mw/Mn of 1.29.

### Synthesis Example 7

Into a 100 mL three-neck flask as a reaction vessel, 0.016 g of azoisobutyronitrile (0.1 mmol), 1.09 g of tert-butylstyrene (6.8 mmol), 2.21 g of 4-nonafluorobutylstyrene (6.8 mmol), 0.12 g of 2-cyano-2-propyldodecyl trithiocarbonate (0.34 mmol) and 11 g of anisole were added and degassing of the mixture was conducted three times under a reduced pressure on a dry ice bath, and a nitrogen atmosphere was provided. After the temperature was elevated to a normal temperature, the mixture was heated with stirring at 80° C. for 5 hrs. Moreover, 0.2 mL of 4-vinylbenzylcyanide (1.5 mmol) was charged with a syringe, and the mixture was further heated with stirring at 80° C. for 3 hrs. This polymerization solution was purified by precipitation in 300 g of cold methanol/ultra pure water=9/1 to collect a yellow solid. Thus obtained yellow solid was dissolved in 100 g of tetrahydrofuran, and thereto were added 1.97 g of azoisobutyronitrile (12 mmol) and 2.02 g of tert-butyldodecyl mercaptan (10 mmol). The mixture was refluxed at 80° C. for 2 hrs to carry out a cleavage reaction of a trithiocarbonate end. The polymerization solution thus obtained was purified by precipitation in 1,000 g of methanol to give a pale yellowish solid. Next, this solid was dried under reduced pressure at 60° C. to give 2.86 g of a white polymer (A-7). The polymer (A-7) had the Mw of 5,600, the Mn of 4,800, and the Mw/Mn of 1.17.

### Synthesis Example 8

Into a 100 mL three-neck flask as a reaction vessel, 0.016 g of azoisobutyronitrile (0.1 mmol), 1.09 g of tert-butylstyrene (6.8 mmol), 2.38 g of 4-(1H,1H,2H,2H-nonafluorohexyl)styrene (6.8 mmol), 0.12 g of 2-cyano-2-propyldodecyl trithiocarbonate (0.34 mmol) and 11 g of anisole were added and degassing of the mixture was conducted three times under a reduced pressure on a dry ice bath, and a nitrogen atmosphere was provided. After the temperature elevated to a normal temperature was confirmed, the mixture was heated with stirring at 80° C. for 5 hrs. Moreover, 0.2 mL of 4-vinylbenzylcyanide (1.5 mmol) was charged with a syringe, and the mixture was further heated with stirring at 80° C. for 3 hrs. This polymerization solution was purified by precipitation in 300 g of cold methanol/ultra pure water=9/1 to collect a yellow solid thus obtained. Next, the yellow solid was dissolved in 100 g of tetrahydrofuran, and thereto were added 1.97 g of azoisobutyronitrile (12 mmol) and 2.02 g of tert-butyldodecyl mercaptan (10 mmol). The mixture was refluxed at 80° C. for 2 hrs to carry out a cleavage reaction of a trithiocarbonate end. The polymerization solution thus obtained was purified by precipitation in 1,000 g of methanol to give a pale yellowish solid. Next, this solid was dried under reduced pressure at 60° C. to give 2.93 g of a white polymer (A-8). The polymer (A-8) had the Mw of 6,400, the Mn of 5,300, and the Mw/Mn of 1.20.

### Synthesis Example 9

Into a 100 mL three-neck flask as a reaction vessel, 0.016 g of azoisobutyronitrile (0.1 mmol), 1.09 g of tert-butylstyrene (6.8 mmol), 1.88 g of 4-perfluoroisopropylstyrene (6.8 mmol), 0.12 g of 2-cyano-2-propyldodecyl trithiocarbonate (0.34 mmol) and 11 g of anisole were added and degassing of the mixture was conducted three times under a reduced pressure on a dry ice bath, and a nitrogen atmosphere was provided. After the temperature elevated to a normal temperature was confirmed, the mixture was heated with stirring at 80° C. for 5 hrs. Moreover, 0.2 mL of 4-vinylbenzylcyanide (1.5 mmol) was charged with a syringe, and the mixture was further heated with stirring at 80° C. for 3 hrs. This polymerization solution was purified by precipitation in 300 g of cold methanol/ultra pure water=9/1 to collect a yellow solid thus obtained. Next, the yellow solid was dissolved in 100 g of tetrahydrofuran, and thereto were added 1.97 g of azoisobutyronitrile (12 mmol) and 2.02 g of tert-butyldodecyl mercaptan (10 mmol). The mixture was refluxed at 80° C. for 2 hrs to carry out a cleavage reaction of a trithiocarbonate end. The polymerization solution thus obtained was purified by precipitation in 1,000 g of methanol to give a pale yellowish solid. Next, this solid was dried under reduced pressure at 60° C. to give 2.87 g of a white polymer (A-9). The polymer (A-9) had the Mw of 5,600, the Mn of 4,600, and the Mw/Mn of 1.212.

### Synthesis Example 10

After a 500 mL flask as a reaction vessel was dried under reduced pressure, 120 g of THF which had been subjected to a distillation dehydrating treatment was charged in a nitrogen atmosphere, and cooled to −78° C. To this THF were charged 1.02 mL of 1,1-diphenylethylene (7.19 mmol), 9.59 mL of a 1 M tetrahydrofuran solution of lithium chloride (4.79 mmol) and 2.47 mL a 1 N cyclohexane solution of sec-butyllithium (sec-BuLi) (2.40 mmol). Moreover, 12.7 mL of methyl methacrylate (0.120 mol) which had been subjected to: adsorptive filtration by means of silica gel for removing the polymerization inhibitor; and a dehydration treatment by distillation was added dropwise over 30 min, and the polymerization system color was ascertained to be orange. During the dropwise addition, the internal temperature of the reaction mixture was carefully controlled so as not to be −60° C. or higher. After completion of the dropwise addition, aging was permitted for 120 min. Next, 2.40 mL of a 1 N toluene solution of ethylene oxide (2.40 mmol) was added, and 1 mL of methanol was further charged to conduct a terminating reaction of the polymerization end. The temperature of the reaction mixture was elevated to the room temperature, and the resulting reaction mixture was concentrated, followed by substitution with MIBK. Thereafter, 1,000 g of a 2% by mass aqueous oxalic acid solution was charged and the mixture was stirred. After leaving to stand, the aqueous underlayer was removed. This operation was repeated three times to remove the Li salt. Thereafter, 1,000 g of ultra pure water was charged and the mixture was stirred, followed by removing the aqueous underlayer. This operation was repeated three times to remove oxalic acid, and then the solution was concentrated. The concentrate was added dropwise into 500 g of methanol to allow the polymer to be precipitated, and the solid was collected on a Buechner funnel. This solid was dried under reduced pressure at 60° C. to give 11.2 g of a white polymer (A-10). The polymer (A-10) had the Mw of 5,200, the Mn of 5,000, and the Mw/Mn of 1.04. The polymer (A-10) was dissolved in propylene glycol monomethyl ether acetate to give a 10% by mass solution.

### Synthesis Example 11

After a 500 mL flask as a reaction vessel was dried under reduced pressure, 120 g of THF which had been subjected to a distillation dehydrating treatment was charged in a nitrogen atmosphere, and cooled to −78° C. To this THF was charged 2.38 mL of a 1 N cyclohexane solution of sec-butyllithium (sec-BuLi) (2.31 mmol). Moreover, 13.3 mL of styrene (0.115 mol) which had been subjected to: adsorptive filtration by means of silica gel for removing the polymerization inhibitor; and a dehydration treatment by distillation was added dropwise over 30 min, and the polymerization system color was ascertained to be orange. During the dropwise addition, the internal temperature of the reaction mixture was carefully controlled so as not to be −60° C. or higher. After completion of the dropwise addition, aging was permitted for 30 min. Next, 1 mL of methanol as a chain-end terminator was charged to conduct a terminating reaction of the polymerization end. The temperature of the reaction mixture was elevated to the room temperature, and the resulting reaction mixture was concentrated, followed by substitution with MIBK. Thereafter, 1,000 g of a 2% by mass aqueous oxalic acid solution was charged and the mixture was stirred. After leaving to stand, the aqueous underlayer was removed. This operation was repeated three times to remove the Li salt. Thereafter, 1,000 g of ultra pure water was charged and the mixture was stirred, followed by removing the aqueous underlayer. This operation was repeated three times to remove oxalic acid, and then the solution obtained was concentrated. The concentrate was added dropwise into 500 g of methanol to allow the polymer to be precipitated, and the solid was collected on a Buechner funnel. This solid was dried under reduced pressure at 60° C. to give 11.7 g of a white polymer (A-11). The polymer (A-11) had the Mw of 5,600, the Mn of 5,300, and the Mw/Mn of 1.06. The polymer (A-11) was dissolved in propylene glycol monomethyl ether acetate to give a 10% by mass solution.

### Synthesis Example 12

After a 500 mL flask as a reaction vessel was dried under reduced pressure, 120 g of THF which had been subjected to a distillation dehydrating treatment was charged in a nitrogen atmosphere, and cooled to −78° C. To this THF was charged 2.38 mL of a 1 N cyclohexane solution of sec-butyllithium (sec-BuLi) (2.30 mmol). Moreover, 13.3 mL of styrene (0.115 mol) which had been subjected to: adsorptive filtration by means of silica gel for removing the polymerization inhibitor; and a dehydration treatment by distillation was added dropwise over 30 min, and the polymerization system color was ascertained to be orange. During the dropwise addition, the internal temperature of the reaction mixture was carefully controlled so as not to be −60° C. or higher. After completion of the dropwise addition, aging was permitted for 30 min. Next, 0.32 mL of 4-chloromethyl-2,2-dimethyl-1,3-dioxolane (2.30 mmol) as a chain-end terminator was charged to conduct a terminating reaction of the polymerization end. Next, 10 g of a 1 N aqueous hydrochloric acid solution was added, and the mixture was heated with stirring at 60° C. for 2 hrs to permit a hydrolysis reaction, whereby a polymer having a diol structure as a terminal group was obtained. The reaction mixture was cooled to room temperature, and the resulting reaction mixture was concentrated, followed by substitution with MIBK. Thereafter, 1,000 g of a 2% by mass aqueous oxalic acid solution was charged and the mixture was stirred. After leaving to stand, the aqueous underlayer was removed. This operation was repeated three times to remove the Li salt. Thereafter, 1,000 g of ultra pure water was charged and the mixture was stirred, followed by removing the aqueous underlayer. This operation was repeated three times to remove oxalic acid, and then the solution obtained was concentrated. The concentrate was added dropwise into 500 g of methanol to allow the polymer to be precipitated, and the solid was collected on a Buechner funnel. This solid was dried under reduced pressure at 60° C. to give 11.3 g of a white polymer (A-12). The polymer (A-12) had the Mw of 5,300, the Mn of 4,900, and the Mw/Mn of 1.08. The polymer (A-12) was dissolved in propylene glycol monomethyl ether acetate to give a 10% by mass solution.

### Preparation of Compositions

### Example 1

A composition (S-1) was prepared by: adding 88.0 g of octafluoropentanol (Daikin Industries, Ltd.) as the solvent (B) to 12.0 g of a solution (10% by mass) containing (A-1) as the polymer (A); stirring the mixture; and then filtering the stirred mixture through a high-density polyethylene filter with fine pores having a pore size of 0.45 μm.

### Example 2

A composition (S-2) was prepared by: adding 88.0 g of propylene glycol monomethyl ether acetate (PGMEA) as the solvent (B) to 12.0 g of a solution (10% by mass) containing (A-2) as the polymer (A); stirring the mixture; and then filtering the stirred mixture through a high-density polyethylene filter with fine pores having a pore size of 0.45 μm.

### Examples 3 to 9 and Comparative Examples 1 to 3

Compositions (S-3) to (S-12) were prepared similarly to Example 2 except that a solution (10% by mass) containing the polymer (A) of the type and the amount blended, and the solvent (B) each shown in Table 1 below were used.

TABLE 1

| | | | Amount blended (mass (g)) | | | | | |
|---|---|---|---|---|---|---|---|---|
| | | | Example 1 | Example 2 | Example 3 | Example 4 | Example 5 | Example 6 |
| Composition | | | S-1 | S-2 | S-3 | S-4 | S-5 | S-6 |
| Solution | A-1 | poly(C₆F₁₃EtMA)-ω-SH | 12.0 | | | | | |
| containing | A-2 | poly(C₆F₁₃EtMA-co-tBuSt)-ω-SH | | 12.0 | | | | |
| (A) | A-3 | poly[(CF₃)₂St-co-tBuSt]-ω-SH | | | 12.0 | | | |
| polymer | A-4 | poly(C₆F₁₃EtMA-co-tBuSt-co-HS)-ω-SH | | | | 12.0 | | |
| (10% by | A-5 | poly(C₆F₁₃EtMA-co-tBuSt-co-tBuOSt)-ω-SH | | | | | 12.0 | |
| mass) | A-6 | poly(C₆F₁₃EtMA-co-tBuSt)-ω-CN | | | | | | 12.0 |
| | A-7 | poly(C₄H₉St-co-tBuSt)-b-poly(StCH₂CN) | | | | | | |
| | A-8 | poly(C₄H₉C₂H₄St-co-tBuSt)-b-poly(StCH₂CN) | | | | | | |
| | A-9 | poly(iC₃F₇St-co-tBuSt-b-oly(StCH₂CN) | | | | | | |
| | A-10 | PMMA-ω-OHp | | | | | | |
| | A-11 | PS-ω-H | | | | | | |
| | A-12 | PS-ω-DOH | | | | | | |
| (B) | B-1 | octafluoropentanol | 88.0 | | | | | |
| Solvent | B-2 | PGMEA | | 88.0 | 88.0 | 88.0 | 88.0 | 88.0 |

| | | | Amount blended (mass (g)) | | | | | |
|---|---|---|---|---|---|---|---|---|
| | | | | | | Comparative | Comparative | Comparative |
| | | | Example 7 | Example 8 | Example 9 | Example 1 | Example 2 | Example 3 |
| Composition | | | S-7 | S-8 | S-9 | S-10 | S-11 | S-12 |
| Solution | A-1 | poly(C₆F₁₃EtMA)-ω-SH | | | | | | |
| containing | A-2 | poly(C₆F₁₃EtMA-co-tBuSt)-ω)-SH | | | | | | |
| (A) | A-3 | poly[(CF₃)₂St-co-tBuSt]-ω-SH | | | | | | |
| polymer | A-4 | poly(C₆F₁₃EtMA-co-tBuSt-co-HS)-ω-SH | | | | | | |
| (10% by | A-5 | poly(C₆F₁₃EtMA-co-tBuSt-co-tBuOSt)-ω-SH | | | | | | |
| mass) | A-6 | poly(C₆F₁₃EtMA-co-tBuSt)-ω-CN | | | | | | |
| | A-7 | poly(C₄H₉St-co-tBuSt)-b-poly(StCH₂CN) | 12.0 | | | | | |
| | A-8 | poly(C₄H₉C₂H₄St-co-tBuSt)-b-poly(StCH₂CN) | | 12.0 | | | | |
| | A-9 | poly(iC₃F₇St-co-tBuSt-b-oly(StCH₂CN) | | | 12.0 | | | |
| | A-10 | PMMA-ω-OHp | | | | 12.0 | | |
| | A-11 | PS-ω-H | | | | | 12.0 | |
| | A-12 | PS-ω-DOH | | | | | | 12.0 |
| (B) | B-1 | octafluoropentanol | | | | | | |
| Solvent | B-2 | PGMEA | 88.0 | 88.0 | 88.0 | 88.0 | 88.0 | 88.0 |

### Evaluations

Each of the compositions prepared as described above was evaluated according to the following method.

### Evaluation of Surface Modification on Metal Substrate, Metalloid Substrate

### Examples 10 to 32 and Comparative Examples 4 to 11

After eight-inch substrates (copper substrate, cobalt substrate, tungsten substrate, tantalum substrate, tantalum nitride film substrate) were immersed n a 5% by mass aqueous oxalic acid solution, they were dried by a nitrogen flow to remove oxidized coating films on the surfaces. The silicon oxide substrate was subjected to a surface treatment with isopropanol.

Next, the compositions prepared as described above were spin-coated by using Track (“TELDSA ACT8” available from Tokyo Electron Limited) at 1,500 rpm, and baked at 150° C. for 180 sec. The substrate was subjected to a separation with PGMEA to remove unreacted polymer. The selective surface modification material formed on the substrate had a thickness of about 0 nm to 5 nm as a result of the measurement of the film thickness with an ellipsometer. Next, the surface contact angle (SCA) value was measured by using a contact angle meter (“Drop master DM-501” available from Kyowa Interface Science Co., LTD.). Furthermore, arrangement density a (chains/nm²) of the polymer (A) (brush) was calculated on the basis of the film thickness according to the following formula (1):

σ=d×L×NA×10⁻²¹/Mn (1)
d: density (g/cm³) of the polymer (A); L: average thickness (nm) of the film; NA: Avogadro's number; and Mn: number average molecular weight of the polymer (A).

With respect to each metal substrate and each silicon oxide substrate, the average thickness (nm), the contact angle)(° and polymer (brush) density (chains/nm²) of the polymer film formed on the surface of the substrate are shown in Table 2, respectively. In Table 2, “-”denotes that the polymer density was not calculated.

### Oxidization-Inhibiting Capability

### Examples 33 to 39, and Comparative Examples 12 and 13

In order to evaluate an oxidization-inhibiting capability of a base material surface by the modification of the base material surface with the composition, time-dependent alterations (one day later, one week later, two weeks later, and one month later) of the average thickness (nm) and the surface contact angle)(° of the polymer (A) were determined on the surface-modified substrate produced by a method similar to that in “Evaluation of Surface Modification on Metal Substrate” described above. The results of the evaluations are shown in Table 3.

TABLE 2

| | Composition | Sample | Thickness (nm) | | SCA(°) | |
|---|---|---|---|---|---|---|
| Copper substrate | | | Copper | Si oxide | Copper | Si oxide |
| | | (Control) | | | 10 | 36 |
| Comparative | S-10 | PMMA-ω-Ohp | 3.5 | 3.6 | 68 | 69 |
| Example 4 | | | | | | |
| Example 10 | S-1 | poly(C₆F₁₇EtMA)-ω-SH | 3.8 | 0.6 | 113 | 39 |
| Example 11 | S-2 | poly(C₆F₁₃EtMA-co-tBuSt)-ω-SH | 3.7 | 0.8 | 107 | 49 |
| Example 12 | S-3 | poly[(CF₃)₂St-co-tBuSt]-ω-SH | 3.7 | 0.7 | 103 | 47 |
| Example 13 | S-5 | poly(C₆F₁₃EtMA-co-tBuSt-co-tBuOSt)-ω-SH | 4.1 | 0.7 | 106 | 46 |
| Example 14 | S-6 | poly(C₆F₁₃EtMA-co-tBuSt)-ω-CN | 3.8 | 0.9 | 105 | 49 |
| Example 15 | S-7 | poly(C₄H₉St-co-tBuSt)-b-poly(StCH₂CN) | 3.9 | 0.6 | 108 | 47 |
| Example 16 | S-8 | poly(C₄H₉C₂H₄St-co-tBuSt)-b-poly(StCH₂CN) | 4.1 | 0.7 | 107 | 46 |
| Example 17 | S-9 | poly(iC₃F₇St-co-tBuSt-b-poly(StCH₂CN) | 3.9 | 0.7 | 111 | 48 |
| Cobalt substrate | | | Cobalt | Si oxide | Cobalt | Si oxide |
| | | (Control) | | | 10 | 36 |
| Comparative | S-11 | PS-ω-H | 0.6 | 0.7 | 42 | 45 |
| Example 5 | | | | | | |
| Comparative | S-12 | PS-ω-DOH | 3.7 | 3.6 | 89 | 88 |
| Example 6 | | | | | | |
| Example 18 | S-1 | poly(C₆F₁₇EtMA)-ω-SH | 3.8 | 0.5 | 113 | 46 |
| Example 19 | S-2 | poly(C₆F₁₃EtMA-co-tBuSt)-ω-SH | 3.7 | 0.4 | 107 | 47 |
| Example 20 | S-3 | poly[(CF₃)₂St-co-tBuSt]-ω-SH | 3.7 | 0.5 | 103 | 46 |
| Example 21 | S-5 | poly(C₆F₁₃EtMA-co-tBuSt-co-tBuOSt)-ω-SH | 4.1 | 0.7 | 106 | 46 |
| Example 22 | S-6 | poly(C₆F₁₃EtMA-co-tBuSt)-ω-CN | 3.8 | 0.5 | 105 | 47 |
| Tungsten substrate | | | W | Si oxide | W | Si oxide |
| | | (Control) | | | 10 | 36 |
| Comparative | S-11 | PS-ω-H | 0.6 | 0.6 | 43 | 44 |
| Example 7 | | | | | | |
| Comparative | S-12 | PS-ω-DOH | 3.6 | 3.6 | 89 | 89 |
| Example 8 | | | | | | |
| Example 23 | S-2 | poly(C₆F₁₃EtMA-co-tBuSt)-ω-SH | 3.7 | 0.5 | 107 | 45 |
| Example 24 | S-3 | poly[(CF₃)₂St-co-tBuSt]-ω-SH | 3.7 | 0.3 | 103 | 39 |
| Example 25 | S-5 | poly(C₆F₁₃EtMA-co-tBuSt-co-tBuOSt)-ω-SH | 4.1 | 0.6 | 106 | 47 |
| Example 26 | S-6 | poly(C₆F₁₃EtMA-co-tBuSt)-ω-CN | 3.8 | 0.5 | 105 | 48 |
| Tantalum substrate | | | Tantalum | Si oxide | Tantalum | Si oxide |
| | | (Control) | | | 50 | 46 |
| Comparative | S-10 | PMMA-ω-Ohp | 3.5 | 3.6 | 69 | 68 |
| Example 9 | | | | | | |
| Comparative | S-12 | PS-ω-DOH | 3.5 | 3.6 | 88 | 72 |
| Example 10 | | | | | | |
| Example 27 | S-2 | poly(C₆F₁₃EtMA-co-tBuSt)-ω-SH | 3.7 | 0.4 | 107 | 44 |
| Example 28 | S-5 | poly(C₆F₁₃EtMA-co-tBuSt-co-tBuOSt)-ω-SH | 4.1 | 0.7 | 106 | 44 |
| Example 29 | S-6 | poly(C₆F₁₃EtMA-co-tBuSt)-ω-CN | 3.8 | 0.5 | 105 | 48 |
| Tantalum nitride substrate | | | TaN | Si oxide | TaN | Si oxide |
| | | (Control) | | | 37 | 46 |
| Comparative | S-12 | PS-ω-DOH | 3.6 | 3.6 | 89 | 88 |
| Example 11 | | | | | | |
| Example 30 | S-2 | poly(C₆F₁₃EtMA-co-tBuSt)-ω-SH | 3.8 | 0.4 | 107 | 44 |
| Example 31 | S-5 | poly(C₆F₁₃EtMA-co-tBuSt-co-tBuOSt)-ω-SH | 4.1 | 0.6 | 106 | 43 |
| Example 32 | S-6 | poly(C₆F₁₃EtMA-co-tBuSt)-ω-CN | 3.7 | 0.5 | 105 | 48 |

From the results shown in Table 2, it was revealed that the compositions of Examples enabled the surface region containing a metal or a metalloid to be conveniently and highly selectively modified with high density.

TABLE 3

| | | One day later | | | | One week later | | | |
|---|---|---|---|---|---|---|---|---|---|
| | | Thickness (nm) | | SCA (°) | | Thickness (nm) | | SCA (°) | |
| | | Copper substrate | | | | | | | |
| | | | Si | | Si | | Si | | Si |
| | Composition | Copper | oxide | Copper | oxide | Copper | oxide | Copper | oxide |
| | | | | 10 | 36 | | | 10 | 36 |
| Comparative | S-10 | 3.5 | 3.6 | 69 | 68 | 3.2 | 3.1 | 54 | 51 |
| Example 12 | | | | | | | | | |
| Comparative | S-11 | 0.6 | 0.6 | 43 | 44 | 0.6 | 0.4 | 37 | 38 |
| Example 13 | | | | | | | | | |
| Example 33 | S-2 | 3.7 | 0.8 | 107 | 49 | 3.7 | 0.8 | 107 | 49 |
| Example 34 | S-4 | 3.7 | 0.7 | 102 | 46 | 3.7 | 0.7 | 102 | 46 |
| Example 35 | S-5 | 4.1 | 0.7 | 106 | 46 | 4.1 | 0.7 | 106 | 46 |
| Example 36 | S-6 | 3.8 | 0.9 | 105 | 49 | 3.8 | 0.9 | 105 | 49 |
| Example 37 | S-7 | 3.9 | 0.6 | 108 | 47 | 3.9 | 0.6 | 108 | 47 |
| Example 38 | S-8 | 4.1 | 0.7 | 107 | 46 | 4.1 | 0.7 | 107 | 46 |
| Example 39 | S-9 | 3.9 | 0.7 | 111 | 48 | 3.9 | 0.7 | 111 | 48 |
| | | Two weeks later | | | | One month later | | | |
| | | Thickness (nm) | | SCA (°) | | Thickness (nm) | | SCA (°) | |
| | | Copper substrate | | | | | | | |
| | | | Si | | Si | | Si | | Si |
| | Composition | Copper | oxide | Copper | oxide | Copper | oxide | Copper | oxide |
| | | | | 10 | 36 | | | 10 | 36 |
| Comparative | S-10 | 2.9 | 2.8 | 51 | 49 | 2.7 | 2.6 | 48 | 49 |
| Example 12 | | | | | | | | | |
| Comparative | S-11 | 0.4 | 0.4 | 29 | 38 | 0.4 | 0.4 | 29 | 38 |
| Example 13 | | | | | | | | | |
| Example 33 | S-2 | 3.5 | 0.6 | 105 | 46 | 3.5 | 0.7 | 105 | 46 |
| Example 34 | S-4 | 3.7 | 0.7 | 102 | 46 | 3.7 | 0.7 | 102 | 46 |
| Example 35 | S-5 | 4.1 | 0.7 | 106 | 46 | 4.1 | 0.7 | 106 | 46 |
| Example 36 | S-6 | 3.3 | 0.8 | 103 | 47 | 3.3 | 0.7 | 103 | 47 |
| Example 37 | S-7 | 3.8 | 0.6 | 107 | 44 | 3.8 | 0.6 | 107 | 44 |
| Example 38 | S-8 | 3.9 | 0.7 | 107 | 45 | 3.9 | 0.7 | 107 | 45 |
| Example 39 | S-9 | 3.7 | 0.7 | 109 | 47 | 3.7 | 0.7 | 109 | 47 |

From the results shown in Table 3, it was revealed that according to the compositions of Examples, the polymer layer formed on the region containing the metal was persistently maintained.

### Evaluation of Surface Modification and Separating Behavior on Striped Substrate of Copper-Silicon Oxide

### Examples 40 to 43, and Comparative Examples 14 and 15

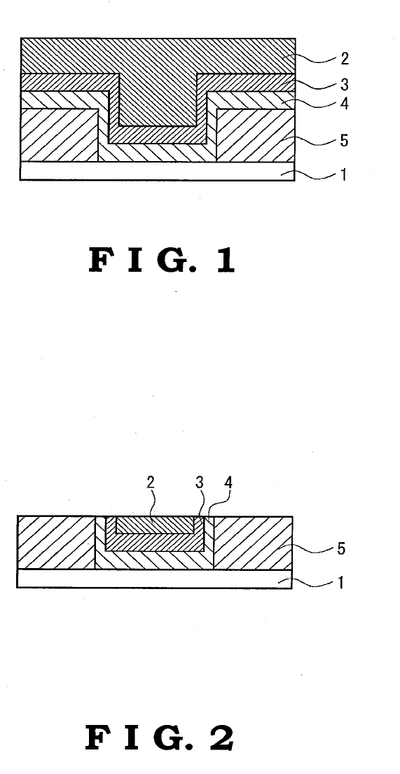

An eight-inch substrate shown in FIG. 1 (Cu-EPC (2): 10,000 Å/Cu-Seed (3): 1,000 Å/TaN Barrier Layer (4): 250 Å/silicon oxide (5): 5,000 Å/silicon wafer (1), 0.18 μm trench) was ground with a CMP slurry to produce a substrate including copper and silicon oxide arranged in a striped shape as shown in FIG. 2 below. Next, this substrate was immersed in a 5% by mass aqueous oxalic acid solution and thereafter dried with a nitrogen flow, whereby the oxidized coating film on the surface was removed.

The compositions prepared as described above were spin-coated on the substrate by using Track (“TELDSA ACT8” available from Tokyo Electron Limited) at 1,500 rpm, and baked at 150° C. for 180 sec. The substrate was subjected to a separation with PGMEA to remove unreacted polymer. Next, the surface was observed under a scanning probe microscope (“S-image” (microscope unit) and “Nano Navi Real” (control station) available from Hitachi High-Technologies Science Corporation), and the film thickness of the coating was calculated from the recess and protrusion.

Average thickness (nm) of the coating film of the polymer formed on each region containing copper or silicon oxide on the copper-silicon oxide striped substrate is each shown in Table 4. In Table 4, “ND” indicates that the thickness was so small that the detection failed.

In addition, the substrate obtained after removing the unreacted polymer was irradiated with a radioactive ray of 254 nm at an intensity of 300 mJ/cm², and then immersed in a mix liquid of methyl isobutyl ketone/2-propanol (2/8 (mass ratio)) for 5 min to remove the layer of the polymer (A) on the substrate.

With respect to “before UV irradiation and immersion” and “after UV irradiation and immersion”, respectively, of the copper-silicon oxide striped substrate obtained as described above, the average thickness (nm) of the polymer film formed on each region containing copper or silicon oxide was determined from the recess and protrusion through observing the surface under a scanning probe microscope (Hitachi High-Technologies Science Corporation, S-image (microscope unit) and Nano Navi Real (control station)). The results of the measurements are shown in Table 4. In Table 4, “ND” indicates that the thickness was so small that the detection failed.

TABLE 4

| | | | Copper-silicon oxide striped substrate | | | |
|---|---|---|---|---|---|---|
| | | | Before UV irradiation/wet | | After UV irradiation/wet | |
| | | | developer | | developer | |
| | | | Thickness (nm) | | Thickness (nm) | |
| | Composition | Sample | Copper | Si oxide | Copper | Si oxide |
| Comparative | S-11 | PS-ω-H | ND | ND | ND | ND |
| Example 14 | | | | | | |
| Comparative | S-12 | PS-ω-DOH | 4.5 | 4.6 | 3.8 | 3.6 |
| Example 15 | | | | | | |
| Example 40 | S-2 | poly(C₆F₁₃EtMA-co-tBuSt)-ω-SH | 5.1 | ND | ND | ND |
| Example 41 | S-4 | poly(C₆F₁₃EtMA-co-tBuSt-co-HS)-ω-SH | 4.4 | ND | ND | ND |
| Example 42 | S-5 | poly(C₆F₁₃EtMA-co-tBuSt-co-tBuOSt)-ω-SH | 4.3 | ND | ND | ND |
| Example 43 | S-6 | poly(C₆F₁₃EtMA-co-tBuSt)-ω-CN | 5.3 | ND | ND | ND |

From the results shown in Table 4, it was revealed that the compositions of Examples enabled a region containing copper to be highly selectively modified, of the copper-silicon oxide substrate. Furthermore, in a case in which the polymer (A) had a structural unit derived from a methacrylic ester having a quaternary carbon atom, the layer of the polymer (A) was ascertained to be removed through a chemical process following UV irradiation and immersion.

The composition, and the modification method and selective modification method of a base material surface of the embodiments of the present invention enable water repellency to be sufficiently and continuously provided through modification of a surface region containing a metal or a metalloid. The pattern-forming method of the embodiment of the present invention enables pattern formation with a more favorable performance. The polymer of the embodiment of the present invention can be suitably used as a polymer component of the composition of the embodiment of the present invention. Therefore, these can be suitably used for working processes of semiconductor devices, and the like, in which microfabrication is expected be further in progress hereafter.

Obviously, numerous modifications and variations of the present invention are possible in light of the above teachings. It is therefore to be understood that within the scope of the appended claims, the invention may be practiced otherwise than as specifically described herein.

1. A composition comprising:
a first polymer comprising:
a first structural unit comprising a fluorine atom; and
a group comprising a first functional group capable of forming a bond with a metal or a metalloid at an end of a main chain or a side chain of the first polymer; and
a solvent.

2. The composition according to claim 1, wherein the first structural unit comprises a fluorinated hydrocarbon group.

3. The composition according to claim 1, wherein the first structural unit is derived from a (meth)acrylic ester comprising a fluorine atom, or from a styrene compound comprising a fluorine atom.

4. The composition according to claim 1, wherein the first structural unit comprises no less than 6 fluorine atoms.

5. The composition according to claim 1, wherein the first functional group is a sulfanyl group, a hydroxy group, a carboxy group, a cyano group, an ethylenic carbon-carbon double bond-containing group, a nitrogen atom-containing group, a phosphorus atom-containing group, an epoxy group, a disulfide group, an alkoxysilyl group or a silanol group.

6. The composition according to claim 1, wherein the metal is a constituent of a metal substance, an alloy, an oxide, a nitride or a silicide, and the metalloid is a constituent of an oxide, a nitride or an oxynitride.

7. The composition according to claim 1, wherein the metal is copper, iron, zinc, cobalt, aluminum, titanium, tin, tungsten, tantalum, zirconium, molybdenum, gold, silver, platinum, palladium or nickel.

8. The composition according to claim 1, wherein the metalloid is silicon.

9. The composition according to claim 1, wherein the first polymer further comprises a second structural unit that is other than the first structural unit and that is derived from substituted or unsubstituted styrene.

10. The composition according to claim 1, which is suitable for modification of a surface of a base material comprising a surface layer comprising a metal or a metalloid.

11. A method for modifying a base material surface, the method comprising:
applying the composition according to claim 1 on a surface of a base material comprising a surface layer comprising a metal or a metalloid to form a coating film; and
heating the coating film.

12. A method for selectively modifying a base material surface, the method comprising:
applying the composition according to claim 1 on a surface of the base material, which comprises a surface layer which comprises a first region comprising a metal and a second region comprising a metalloid, to form a coating film;
heating the coating film; and
removing with a rinse agent a portion of the coating film, the portion being formed on at least one of the first region and the second region.

13. The method according to claim 12, further comprising
bringing an alcohol, a dilute acid, a hydrogen peroxide solution, ozone or plasma into contact with the surface of the base material after the removing.

14. The method according to claim 12, further comprising etching away the first polymer from the surface of the base material after the removing of the portion of the coating film.

15. A pattern-forming method comprising:
applying the composition according to claim 1 on a surface of the base material, which comprises a surface layer which comprises a first region comprising a metal and a second region comprising a metalloid, to form a coating film;
heating the coating film;
removing with a rinse agent a portion of the coating film, the portion being formed on at least one of the first region and the second region;
depositing a pattern on the surface of the base material after the removing, with a CVD method or an ALD method; and
etching away the first polymer from the surface of the base material after the removing of the portion of the coating film.

16. The pattern-forming method according to claim 15, further comprising bringing an alcohol, a dilute acid, ozone or plasma into contact with the surface of the base material after the removing of the portion of the coating film.

17. A polymer comprising:
a structural unit comprising a fluorine atom; and
at an end of a main chain or a side chain of the polymer, a group comprising a functional group capable of forming a bond with a metal or a metalloid.
